(19) United States
(12) Patent Application Publication
(10) Pub. No.: US 2026/0169382 A1
(43) Pub. Date: Jun. 18, 2026

(54) PHOTOSENSITIVE RESIN FILM AND USES THEREOF

(71) Applicant: CHANG CHUN PLASTICS CO., LTD., TAIPEI CITY (TW)

(72) Inventors: ZIH-I CHUANG, TAIPEI CITY (TW); YUN-JUNG WU, TAIPEI CITY (TW); E-MING HO, TAIPEI CITY (TW)

(21) Appl. No.: 19/213,556

(22) Filed: May 20, 2025

(30) Foreign Application Priority Data
Dec. 18, 2024 (CN) 202411867068.X
Dec. 18, 2024 (TW) 113149450

(51) Int. Cl. G03F 7/038; H10F 39/00

(52) U.S. Cl. CPC G03F 7/0385; G03F 7/0382; H10F 39/804

(57) ABSTRACT

A photosensitive resin film having a thickness T in μm is provided. When the photosensitive resin film is characterized by ultraviolet-visible spectroscopy, a resulting spectrum has an absorbance A₃₅₅ at 355 nm, and 0.003<A₃₅₅/T≤0.03. The spectrum has at least one point within a first wavelength range where the first derivative equals 0 and the second derivative is less than 0, and the point each independently has an A_{w1}/T value, wherein w1 represents corresponding wavelength of the point, A_{w1} represents a corresponding absorbance, and 0.003≤A_{w1}/T. The first wavelength range is from greater than 450 nm to 780 nm, and the thickness T ranges from 20 μm to 200 μm.

### CLAIM FOR PRIORITY

This application claims the benefit of China Patent Application No. 202411867068.X filed on Dec. 18, 2024 and the benefit of Taiwan Patent Application No. 113149450 filed on Dec. 18, 2024, the subject matters of which are incorporated herein in their entirety by reference.

### BACKGROUND OF THE INVENTION

### Field of the Invention

The present application provides a photosensitive resin film, particularly a photosensitive resin film having specific light absorption properties. The photosensitive resin film of the present application is used for forming a package structure comprising a semiconductor element.

### Descriptions of the Related Art

Photosensitive resin films are films that undergo chemical changes after exposure to light. Depending on the changes after light exposure and development, photosensitive resin films can be categorized into positive and negative photosensitive resin films. In positive photosensitive resin films, the parts exposed to light dissolve during development, leaving behind the unexposed parts. In negative photosensitive resin films, the parts not exposed to light dissolve during development, leaving behind the parts exposed to light. Due to their easy patterning characteristics, photosensitive resin films are widely used in the packaging of semiconductor components, including the packaging of CMOS (Complementary Metal-Oxide-Semiconductor) image sensors.

CMOS image sensors are semiconductor devices used to capture digital images. Their advantages in high resolution, high speed, low light, etc., make them widely used in various fields that require image capture, such as smart phones, digital cameras, web cameras, car surround systems, advanced driver assistance systems (ADAS) and so on.

In general, a package structure of a CMOS image sensor is arranged by disposing a patterned structure formed after curing a photosensitive resin layer of a glass plate on a sensor chip, and the patterned structure formed surrounds the periphery of the photosensitive area of the sensor chip. However, the light passing through the glass plate may be partially reflected by the patterned structure, thereby affecting the photosensitive area and causing glare problems. This will have serious safety risks in applications such as automotive fields, including car surround systems and advanced driving assistance systems. In addition, with the trend of miniaturization of CMOS image sensors, the package structure must also be miniaturized accordingly. Therefore, there is an urgent need for a packaging material that can achieve a high aspect ratio, high adhesion, and high pattern accuracy.

### SUMMARY OF THE INVENTION

Given the aforementioned technical problems, the present application aims to provide a photosensitive resin film which can meet the need of low light transmittance, anti-glare and high pattern accuracy. The photosensitive resin film can particularly have high adhesion.

Specifically, an objective of the present application is to provide a photosensitive resin film, which has a thickness T in μm,
wherein, when the photosensitive resin film is characterized by ultraviolet-visible spectroscopy, a resulting spectrum has an absorbance A₃₅₅ at 355 nm, and 0.003<A₃₅₅/T≤0.03;
the spectrum has at least one point within a first wavelength range where a first derivative equals 0 and a second derivative is less than 0, and the point each independently has an A_{w1}/T value, wherein w1 represents a corresponding wavelength of the point, A_{w1} represents a corresponding absorbance, and 0.003≤A_{w1}/T, preferably 0.003≤A_{w1}/T≤0.08, more preferably 0.003≤A_{w1}/T≤0.03; and
the first wavelength range is from greater than 450 nm to 780 nm, more particularly greater than 480 nm to 730 nm, and the thickness T ranges from 20 μm to 200 μm.

In one embodiment of the present application, the ultraviolet-visible spectroscopy is measured by using an ultraviolet-visible spectrophotometer under the following conditions: the photosensitive resin film is placed perpendicularly to a direction of incidence of light; a diffraction grating is configured as an optical splitter; a testing temperature of 25° C. is applied; a testing pressure of 1 atm is applied; an analysis mode of absorbance is used; a scanning wavelength range of 190 nm to 1100 nm is used; air serves as a blank sample; a scanning velocity of 2200 nm/min is used; a switch wavelength at which a light source is switched from a deuterium lamp to a tungsten lamp is 340.8 nm; a sampling interval of 0.2 nm is used; and a slit width of 2.0 nm is used.

In one embodiment of the present application, the spectrum has an absorbance A₄₅₀ at 450 nm, and 0≤A₄₅₀/T≤0.003.

In one embodiment of the present application, an absorbance of the spectrum at each wavelength within a second wavelength range is independently denoted as A_{w2}, with w2 representing a corresponding wavelength of the absorbance, and 0≤A_{w2}/T≤0.003, wherein the second wavelength range is from 440 nm to 470 nm.

In one embodiment of the present application, the photosensitive resin film is a negative dry film.

In one embodiment of the present application, the photosensitive resin film comprises an epoxy film.

Another objective of the present application is to provide a composite film, which comprises the aforementioned photosensitive resin film, and a protective film on at least one surface of the photosensitive resin film.

Still another objective of the present application is to provide a package structure, comprising:
a substrate;
a semiconductor element electrically connected to the substrate; and
a package for encapsulating the semiconductor element,
wherein a material of the package comprises a cured product of the aforementioned photosensitive resin film.

In one embodiment of the present application, the semiconductor element is an image sensor chip, wherein the image sensor chip has a photosensitive area; and the material of the package comprises a first portion formed from a cured product of the aforementioned photosensitive resin film, and a second portion formed from a transparent material, with the first portion laterally surrounding the image sensor chip and the second portion being disposed above the photosensitive area.

### BRIEF DESCRIPTION OF THE DRAWINGS

Not applicable.

### DESCRIPTION OF THE PREFERRED EMBODIMENTS

Hereinafter, some embodiments of the present application will be described in detail. However, the present application may be embodied in various embodiments and should not be limited to the embodiments described in the specification.

Unless additionally explained, the expressions “a,” “the,” or the like, as recited in the specification and the claims, should include both the singular and plural forms.

Unless additionally explained, the expressions “first,” “second,” or the like, as recited in the specification and the claims, are used solely to distinguish the illustrated elements or components without special meanings. These expressions are not used to represent any priority.

The advantage of the present application over prior art particularly lies in providing a photosensitive resin film with anti-glare, low light transmittance, and high pattern accuracy (the cross-sectional profile of the pattern formed after exposure is good) by controlling the absorbance conditions of the photosensitive resin film to light of specific wavelengths. The photosensitive resin film can particularly have high adhesion. Details regarding the photosensitive resin film of the present application and its applications are provided below.

### 1. Photosensitive Resin Film

The photosensitive resin film of the present application refers to a film comprising a photosensitive resin composition, and can be a positive photosensitive resin film or a negative photosensitive resin film. In one embodiment of the present application, the photosensitive resin film is a negative photosensitive resin film. That is, after light exposure of the photosensitive resin film, the parts that are not exposed to light will dissolve during development, leaving behind the parts exposed to light.

Before the use of a photosensitive resin film, it is common to provide a protective film that provides protection and support functions on a surface of the photosensitive resin film to form a structure of a composite film, to facilitate the storage of the photosensitive resin film and to protect the photosensitive resin film from contamination or damage. Unless additionally explained, the “thickness” and “absorbance” recited in the specification and claims are described with respect to the photosensitive resin film itself and do not include other parts such as a protective film that is used in combination with the photosensitive resin film.

In one embodiment of the present application, the photosensitive resin film is a dry film, that is, a photosensitive resin film with low solvent content. The aforementioned low solvent content means that the amount of solvent based on the total weight of the photosensitive resin film is 10 wt % or less, specifically 5 wt % or less, more specifically 0.1 wt % to 4 wt %. Compared with ink-like or liquid wet films, dry films are less likely to flow or deform due to their low solvent content, and can be attached to a substrate without additional process such as coating, drying, or the like. Therefore, dry films are easy to control and have good operability.

The thickness of the photosensitive resin film of the present application can be adjusted depending on the need. In one embodiment of the present application, the photosensitive resin film has a high thickness. Specifically, the photosensitive resin film can have a thickness of 20 μm to 200 μm. For example, the thickness of the photosensitive resin film can be 20 μm, 30 μm, 40 μm, 50 μm, 60 μm, 70 μm, 80 μm, 90 μm, 100 μm, 110 μm, 120 μm, 130 μm, 140 μm, 150 μm, 160 μm, 170 μm, 180 μm, 190 μm, or 200 μm, or within a range between any two of the values described herein.

The photosensitive resin film of the present application can be formed by a single photosensitive resin layer, or by stacking two or more photosensitive resin layers. For example, the photosensitive resin film of the present application can be formed by stacking two, three or four photosensitive resin layers, but the present application is not limited thereto.

### 1.1. Light Absorption Properties of Photosensitive Resin Film

### [A₃₅₅/T]

The photosensitive resin film of the present application has specific light absorption properties. Specifically, when the photosensitive resin film is characterized by ultraviolet-visible spectroscopy, a resulting spectrum has an absorbance A₃₅₅ at 355 nm, and the relation between A₃₅₅ and thickness T (unit: μm) satisfies 0.003<A₃₅₅/T≤0.03. For example, the values of A₃₅₅/T can be 0.0035, 0.004, 0.0045, 0.005, 0.0055, 0.006, 0.0065, 0.007, 0.0075, 0.008, 0.0085, 0.009, 0.0095, 0.01, 0.0105, 0.011, 0.0115, 0.012, 0.0125, 0.013, 0.0135, 0.014, 0.0145, 0.015, 0.0155, 0.016, 0.0165, 0.017, 0.0175, 0.018, 0.0185, 0.019, 0.0195, 0.02, 0.0205, 0.021, 0.0215, 0.022, 0.0225, 0.023, 0.0235, 0.024, 0.0245, 0.025, 0.0255, 0.026, 0.0265, 0.027, 0.0275, 0.028, 0.0285, 0.029, 0.0295, or 0.03, or within a range between any two of the values described herein. If the value of A₃₅₅/T is less than the aforementioned range, the photosensitive resin film will not have sufficient reactivity after light exposure, resulting in insufficient photocuring. If the value of A₃₅₅/T is higher than the aforementioned range, the photosensitive resin film will not be able to form a high-accuracy pattern after light exposure and development, and the cross-sectional profile will be poor.

### [A_{w1}/T]

In addition, when the photosensitive resin film is characterized by ultraviolet-visible spectroscopy, in addition to satisfying the condition of 0.003<A₃₅₅/T≤0.03, the resulting spectrum has at least one point within a first wavelength range where a first derivative equals 0 and a second derivative is less than 0; that is, the resulting spectrum within a first wavelength range has at least one absorption peak. The aforementioned point each independently has an A_{w1}/T value, wherein w1 represents a corresponding wavelength of the point, A_{w1} represents a corresponding absorbance. The aforementioned first wavelength range ranges from greater than 450 nm to 780 nm, more specifically, greater than 480 nm to 730 nm. In the present application, the relation between A_{w1} and thickness T (unit: μm) satisfies 0.003≤A_{w1}/T, preferably satisfies 0.003≤A_{w1}/T≤0.08, more preferably satisfies 0.003≤A_{w1}/T≤0.03. For example, the value of A_{w1}/T can be 0.003, 0.004, 0.005, 0.006, 0.007, 0.008, 0.009, 0.01, 0.011, 0.012, 0.013, 0.014, 0.015, 0.016, 0.017, 0.018, 0.019, 0.02, 0.021, 0.022, 0.023, 0.024, 0.025, 0.026, 0.027, 0.028, 0.029, or 0.03, or within a range between any two of the values described herein. If the value of A_{w1}/T falls within the aforementioned range, the effects of low glare and low light transmittance are provided. Additionally, within the above preferred range, the effects of low glare and low light transmittance can be achieved while reducing the influence on the adhesion and pattern accuracy of the photosensitive resin film.

### [A₄₅₀/T]

In one preferred embodiment of the present application, when the photosensitive resin film is characterized by ultraviolet-visible spectroscopy, in addition to satisfying the conditions of 0.003<A₃₅₅/T≤0.03 and 0.003≤A_{w1}/T, there is no light absorption, substantially no light absorption, or only a small amount of light absorption at 450 nm. Specifically, when the photosensitive resin film is characterized by ultraviolet-visible spectroscopy, the resulting spectrum has an absorbance A₄₅₀ at 450 nm, and the relation between A₄₅₀ and thickness T (unit: μm) satisfies 0≤A₄₅₀/T≤0.003, preferably satisfies 0≤A₄₅₀/T≤0.0025. For example, the value of A₄₅₀/T can be 0, 0.0005, 0.001, 0.0015, 0.002, or 0.0025, or within a range between any two of the values described herein. In the above preferred range, the photosensitive resin film can have better pattern accuracy and adhesion.

### [A_{w2}/T]

In one preferred embodiment of the present application, when the photosensitive resin film is characterized by ultraviolet-visible spectroscopy, in addition to satisfying the condition of 0.003<A₃₅₅/T≤0.03, the spectrum has the aforementioned technical feature of 0.003≤A_{w1}/T within the first wavelength range of greater than 480 nm to 730 nm and has no light absorption, substantially no light absorption, or only a small amount of light absorption within the second wavelength range. The second wavelength range is from 440 nm to 470 nm. Specifically, when the photosensitive resin film is characterized by ultraviolet-visible spectroscopy, an absorbance of the spectrum at each wavelength within the second wavelength range is independently denoted as A_{w2}, and satisfies the condition of 0≤A_{w2}/T≤0.003, wherein w2 represents a corresponding wavelength of the absorbance. For example, A_{w2}/T can be independently 0, 0.0005, 0.001, 0.0015, 0.002, 0.0025, or 0.003, or within a range between any two of the values described herein. In the above preferred range, the photosensitive resin film can have better pattern accuracy and adhesion.

In the present application, the aforementioned ultraviolet-visible spectroscopy is measured using a ultraviolet-visible spectrophotometer under the following conditions: the photosensitive resin film is placed perpendicularly to a direction of incidence of source; a diffraction grating is configured as an optical splitter; a testing temperature of 25° C. is applied; a testing pressure of 1 atm is applied; an analysis mode of absorbance is used; a scanning wavelength range of 190 nm to 1100 nm is used; air serves as a blank sample; a scanning velocity of 2200 nm/min is used; a switch wavelength at which a light source is switched from a deuterium lamp to a tungsten lamp is 340.8 nm; a sampling interval of 0.2 nm is used; and a slit width of 2.0 nm is used. Under the aforementioned testing conditions, a photosensitive resin film sample used for analysis is obtained by cutting a photosensitive resin film into a size of 5 cm×3 cm at any position along the transverse direction (TD) and the machine direction (MD); or by cutting a composite film comprising a photosensitive resin film and protective films on both surfaces of the photosensitive resin film into a size of 5 cm×3 cm at any position along the transverse direction and the machine direction, and then removing the protective films on both surfaces of the cut photosensitive resin film. The photosensitive resin film must be placed perpendicularly to the direction of incidence of light in order to correctly measure the absorbance of the photosensitive resin film. The wavelength of the tungsten lamp used as the incident light source is 340.8 nm. In addition, the “sampling interval” refers to that, in the scanning wavelength range of 190 nm to 1100 nm, a data point is taken every 0.2 nm, and the obtained value is recorded.

The light absorption properties of the photosensitive resin film of the present application can be controlled by adjusting the components of the photosensitive resin film or process conditions of the photosensitive resin film. For example, the components of the photosensitive resin film can be adjusted by the type and amount of additives used. The additives include, but not limited to, photopolymerization initiators, light absorbers, dyes, or the like. The process conditions of the photosensitive resin film can be, for example, drying conditions. Persons having ordinary skill in the art would be able to prepare a photosensitive resin film with the aforementioned light absorption properties by referring to the specification of the subject application, particularly relying on the specific illustrations in the Examples.

### 1.2. Other Properties of Photosensitive Resin Film

With the premise that A₃₅₅/T and A_{w1}/T satisfy the aforementioned ranges, other properties of the photosensitive resin film of the present application can be adjusted according to the required application.

For example, the photosensitive resin film can be adjusted to have an appropriate film tensile. The film tensile refers to an adhesion force between a photosensitive resin film and a protective film covering it, expressed by the force required to vertically tear the protective film of a specific size from the photosensitive resin film. The protective film can be a PET protective film or a PE protective film. In common, the lower film tensile a photosensitive resin film has, the harder and more elastic the photosensitive resin film is; the higher film tensile a photosensitive resin film has, the softer and stickier the photosensitive resin film is. The film tensile is determined by the following way: attaching a protective film to a surface of a photosensitive resin film to form a composite film, cutting the composite film into a size of 10 cm×10 cm, then cutting the protective film into a width of 50 mm in the transverse direction (TD), fixing the composite film on a stage of a tensile testing machine, peeling off the cut 50 mm-width protective film, sticking a tape on the inside of the protective film (that is, the side facing the photosensitive resin film) and fixing to the tensile axis of the tensile testing machine such that the tensile direction is perpendicular to the stage, moving the stage in the transverse direction and toward to the inside of the peeled protective film at a speed of 70 mm/min, and then measuring the tensile after the protective film is torn 2 cm in the transverse direction (TD). The unit of film tensile is g/50 mm.

In one embodiment of the present application, the film tensile of the photosensitive resin film is 2 g/50 mm or higher, more specifically from 2 g/50 mm to 1000 g/50 mm, such that the adhesion is better. For example, the film tensile of the photosensitive resin film can be 2 g/50 mm, 5 g/50 mm, 10 g/50 mm, 50 g/50 mm, 100 g/50 mm, 200 g/50 mm, 300 g/50 mm, 400 g/50 mm, 500 g/50 mm, 600 g/50 mm, 700 g/50 mm, 800 g/50 mm, 900 g/50 mm, or 1000 g/50 mm, or within a range between any two of the values described herein.

### 1.3. The Composition of Photosensitive Resin Film

With the premise that A₃₅₅/T and A_{w1}/T satisfy the aforementioned ranges, the composition of the photosensitive resin film can be adjusted according to the required application. In one embodiment of the present application, the photosensitive resin film is an epoxy resin-based photosensitive resin film, which contains an epoxy resin and optionally contains an ethylenically unsaturated compound, a photopolymerization initiator, and other additives.

### 1.3.1. Epoxy Resin

Examples of the epoxy resin include, but not limited to, a bisphenol A epoxy resin, a bisphenol F epoxy resin, a bisphenol S epoxy resin, a bisphenol A novolac epoxy resin, a novolac epoxy resin, an alkyl novolac epoxy resin, a phenol novolac epoxy resin, a cresol novolac epoxy resin, a cycloaliphatic-based epoxy resin, a biphenyl-based epoxy resin, an aralkyl-based epoxy resin, a naphthalene ring-based epoxy resin, a naphthol-based epoxy resin, a biphenyl aralkyl-based epoxy resin, a fluorene-based epoxy resin, an xanthene-based epoxy resin, a dicyclopentadiene-based epoxy resin, a triglycidyl polyisocyanate, and an oxygen heterocycle-20 based epoxy resin. Each of the aforementioned epoxy resins can be used alone or in combination. In one embodiment of the present application, a bisphenol A epoxy resin, a bisphenol A novolac epoxy resin, a phenol novolac epoxy resin, a cresol novolac epoxy resin, an aliphatic-based epoxy resin, or an oxetane epoxy resin is used.

In the photosensitive resin film of the present application, based on the total weight of the photosensitive resin film, the amount of the epoxy resin can be 50 wt % to 99 wt %, specifically, 55 wt % to 98 wt %, more specifically, 60 wt % to 95 wt %. For example, based on the total weight of the photosensitive resin film, the amount of the epoxy resin can be 50 wt %, 51 wt %, 52 wt %, 53 wt %, 54 wt %, 55 wt %, 56 wt %, 57 wt %, 58 wt %, 59 wt %, 60 wt %, 61 wt %, 62 wt %, 63 wt %, 64 wt %, 65 wt %, 66 wt %, 67 wt %, 68 wt %, 69 wt %, 70 wt %, 71 wt %, 72 wt %, 73 wt %, 74 wt %, 75 wt %, 76 wt %, 77 wt %, 78 wt %, 79 wt %, 80 wt %, 81 wt %, 82 wt %, 83 wt %, 84 wt %, 85 wt %, 86 wt %, 87 wt %, 88 wt %, 89 wt %, 90 wt %, 91 wt %, 92 wt %, 93 wt %, 94 wt %, 95 wt %, 96 wt %, 97 wt %, 98 wt %, or 99 wt %, or within a range between any two of the values described herein.

### 1.3.2. Ethylenically Unsaturated Compound

The ethylenically unsaturated compound refers to a compound with at least one reactive ethylene functional group, for example, a bifunctional compound with two reactive ethylene functional groups. Examples of the ethylenically unsaturated compound include, but are not limited to, ethoxylated trimethylolpropane triacrylate, ethoxylated bisphenol-A diacrylate, ethoxylated bisphenol-A dimethacrylate, tripropylene glycol diacrylate, 1,6-hexanediol diacrylate, polypropylene glycol diacrylate, tris((meth)acryloxyisocyanate) hexamethylene isocyanurate, ethoxylated urethane di(meth)acrylate, propoxylated urethane di(meth)acrylate, ethoxylated/propoxylated urethane di(meth)acrylate, ethoxylated tris(methacryloxyisocyanate) hexamethylene isocyanurate, acrylated tris(methacryloxyisocyanate) hexamethylene isocyanurate, and ethoxylated/propoxylated tris(methacryloxyisocyanate) hexamethylene isocyanurate. In one embodiment of the present application, ethoxylated trimethylolpropane triacrylate is used.

In the photosensitive resin film of the present application, based on the total weight of the photosensitive resin film, the amount of the ethylenically unsaturated compound can be 0 wt % to 70 wt %. For example, based on the total weight of the photosensitive resin film, the amount of the ethylenically unsaturated compound can be 5 wt %, 10 wt %, 15 wt %, 20 wt %, 25 wt %, 30 wt %, 35 wt %, 40 wt %, 45 wt %, 50 wt %, 55 wt %, 60 wt %, 65 wt %, or 70 wt %, or within a range between any two of the values described herein.

### 1.3.3. Photopolymerization Initiator

Examples of the photopolymerization initiator include, but are not limited to, imidazole-based compounds, ketone-based compounds, quinone-based compounds, benzoin-based or benzoin ether-based compounds, polyhalogenated compounds, triazine-based compounds, organic peroxide compounds, and onium salt compounds. The aforementioned photopolymerization initiators can be used alone or in combination. In one embodiment of the present application, the onium salt compounds are used. Examples of the aforementioned onium salt compounds include, but are not limited to, diaryliodonium salts and triarylsulfonium salts obtained from diphenyliodonium, 4,4′-dichlorodiphenyliodonium, 4,4′-dimethoxydiphenyliodonium, 4,4′-di-tert-butyldiphenyliodonium, 4-methyl-4′-isopropyldiphenyliodonium, or 3,3′-dinitrodiphenyl iodonium in combination with chloride, bromide, tetrafluoroborate, hexafluorophosphate, hexafluoroarsenate, hexafluoroantimonate, and tetrakis(pentafluorophenyl) borate, or trifluoromethanesulfonic acid.

In the photosensitive resin film, the amount of the photopolymerization initiator based on the total weight of the photosensitive resin film can be 0.5 wt % to 10 wt %, more specifically 1 wt % to 5 wt %. For example, the amount of the photopolymerization initiator based on the total weight of the photosensitive resin film can be 0.5 wt %, 1 wt %, 1.5 wt %, 2 wt %, 2.5 wt %, 3 wt %, 3.5 wt %, 4 wt %, 4.5 wt %, 5 wt %, 5.5 wt %, 6 wt %, 6.5 wt %, 7 wt %, 7.5 wt %, 8 wt %, 8.5 wt %, 9 wt %, 9.5 wt %, or 10 wt %, or within a range between any two of the values described herein.

### 1.3.4. Additives

With the premise that A₃₅₅/T and A_{w1}/T satisfy the aforementioned ranges, the photosensitive resin film of the present application can further comprise additives in order to improve the properties of the photosensitive resin film. The examples of the additives include, but not limited to, light absorbers, dyes, pigments, radical inhibitors, surfactants, tougheners, and plasticizers. Each of the aforementioned additives can be used alone or in combination. In one embodiment of the present application, the photosensitive resin film can further comprise silane coupling agents, light absorbers and dyes.

In the photosensitive resin film, the amount of the additives based on the total weight of the photosensitive resin film preferably is less than 20 wt %. For example, the amount of the additives based on the total weight of the photosensitive resin film can be 1 wt %, 2 wt %, 3 wt %, 4 wt %, 5 wt %, 6 wt %, 7 wt %, 8 wt %, 9 wt %, 10 wt %, 11 wt %, 12 wt %, 13 wt %, 14 wt %, 15 wt %, 16 wt %, 17 wt %, 18 wt %, or 19 wt %, or within a range between any two of the values described herein.

### 1.4. Preparation of Photosensitive Resin Film

The preparation method of the photosensitive resin film of the present application is not particularly limited. Persons having ordinary skill in the art would be able to prepare the photosensitive resin film by referring to the specification of the subject application. For example, each of the components of the photosensitive resin film can be uniformly mixed by using a stirrer, and dissolved or dispersed in a solvent to prepare a resin composition. Subsequently, the resin composition is coated onto a substrate, and then dried to obtain a photosensitive resin film.

The coating method of the resin composition is not particularly limited and can be any existing coating method commonly used in the field of the present application. Examples of the existing coating methods include, but are not limited to, gravure coating, reverse roll coating, die coating, air scraper coating, scraper coating, rod coating, scraper rod coating, curtain coating, knife coating, transfer roll coating, extrusion press coating, dip coating, kiss coating, spray coating, calendar coating, and extrusion coating.

A detailed preparation method of the photosensitive resin film of the present application is illustrated in the Examples below.

### 2. Composite Film

Generally, before a photosensitive resin film is used, protective films that provide protection and support functions can be applied to both surfaces of the photosensitive resin film. This facilitates the storage of the photosensitive resin film and protects it from contamination or damage. Therefore, the present application also provides a composite film, which comprises the aforementioned photosensitive resin film and a protective film on at least one surface of the photosensitive resin film. In a preferred embodiment of the present application, protective films are provided on both surfaces of the photosensitive resin film, and the materials of the protective films on the two different surfaces of the photosensitive resin film can be identical or different.

The type of the protective films is not particularly limited and can be made of any conventional material known in the art. For example, the protective films that can be used in the present application can be selected from the group consisting of a polyethylene terephthalate film (PET film), a polyolefin film and composites thereof. Examples of the polyolefin film include, but are not limited to, a polyethylene film (PE film) and a polypropylene film (PP film), such as an oriented polypropylene film. The composite can be a composite of a polyethylene terephthalate film and a polyolefin film or a composite of different polyolefin films. In a preferred embodiment of the present application, the composite film comprises PET films formed on the two surfaces of the photosensitive resin film; or the composite film comprises a PET film on one surface of the photosensitive resin film and a PE film on the other surface of the photosensitive resin film.

The preparation method of the composite film of the present application is not particularly limited and can be any existing method commonly used in the field of the present application. For example, the composite film can be prepared by stacking protective films on both surfaces of the photosensitive resin film to provide a superimposed object and pressing the superimposed object to obtain the composite film. Alternatively, the composite film can be prepared by the following way: forming a photosensitive resin film on a first protective film by coating a resin composition of forming a photosensitive resin film on the first protective film followed by drying; attaching a second protective film to the surface of the photosensitive resin film which is not in contact with the first protective film; and then obtaining a composite film. Alternatively, the composite film can be prepared by extruding a resin composition of forming a photosensitive resin film between two protective films with a constant distance, and then drying to form a photosensitive resin film between the two protective films.

### 3. Package Structure

A cured product of the photosensitive resin film of the present application can be used as a material of a package to prepare a package structure for a semiconductor element. Therefore, the present application further provides a package structure, comprising a substrate, a semiconductor element electrically connected to the substrate, and a package for encapsulating the semiconductor element, wherein the material of the package comprises a cured product of the aforementioned photosensitive resin film.

The type or function of the aforementioned semiconductor element Is not particularly limited. In one embodiment of the present application, the semiconductor element can be an image sensor chip, and the image sensor chip can have a photosensitive area. In the case where the semiconductor element is the image sensor chip, the material of the package can comprise, for example, a first portion formed from the cured product of the aforementioned photosensitive resin film and a second portion formed from a transparent material, wherein the first portion laterally surrounds the image sensor chip, the second portion is disposed above the photosensitive area, and the first portion can be directly connected to the second portion or connected to the second portion through a mediator to form the package. In addition, the first portion can be directly connected to the substrate or connected to the substrate through a mediator. Or, the first portion can be directly connected to a non-photosensitive area of the image sensor chip, or connected to the non-photosensitive area of the image sensor chip through a mediator.

### 4. Examples

### 4.1. Testing Methods

### [Thickness of Photosensitive Resin Film]

The prepared composite film comprising the photosensitive resin film is cut into a size of 5 cm×3 cm and the protective films on both surfaces the photosensitive resin film are removed. The resulting photosensitive resin film is placed on a base (MS-11C base) of a film thickness meter (Model: Nikon Digimicro MFC-101+MS-11C, purchased from Nikon), and an MFC-101 meter is used to conduct measurement under a pressure of 140 gf. The thickness of the photosensitive resin film at 10 different points is measured and averaged.

### [Absorbance of Photosensitive Resin Film]

The prepared composite film comprising the photosensitive resin film is cut into a size of 5 cm×3 cm and the protective films on both surfaces the photosensitive resin film are removed. The resulting photosensitive resin film is subjected to absorbance measurement using an ultraviolet-visible spectrophotometer (model: Shimadzu UV-1601, purchased from Shimadzu) in the following manner. The photosensitive resin film is placed perpendicularly to a direction of incident of light and analyzed to obtain absorbance spectrum under the following conditions: a diffraction grating is configured as an optical splitter; a testing temperature of 25° C. is applied; a testing pressure of 1 atm is applied; an analysis mode of absorbance is used; a scanning wavelength range of 190 nm to 1100 nm is used; air serves as a blank sample; a scanning velocity of 2200 nm/min is applied; a switch wavelength at which a light source is switched from a deuterium lamp to a tungsten lamp is 340.8 nm; a sampling interval of 0.2 nm is used; a slit width of 2.0 nm is used; and a Shimadzu UV Probe V1.11 software is used.

### [Film Tensile]

The prepared composite film comprising the photosensitive resin film is cut into a size of 10 cm×10 cm, and then the PET protective film is cut into a width of 50 mm in the transverse direction (TD). The composite film is fixed on a stage of a tensile testing machine (model: FM-50N, purchased from YOTEC) by a double-sided tape. The cut PET protective film with 50 mm-width is peeled off, a tape is sticked to the inside of the PET protective film (i.e., the side facing the photosensitive resin film) and fixed to a tensile axis of the tensile testing machine such that the tensile direction is perpendicular to the stage. The stage is moved in the transverse direction and toward to the inside of the peeled PET protective film at a speed of 70 mm/min, and then a force needed to tear 2 cm of the PET protective film is measured as a film tensile. The unit of film tensile is g/50 mm.

### [Cross-Sectional Shape of Photoresist Pattern]

A low-alkali glass with a thickness of 2 mm is preheated at 80° C. for 10 minutes in a batch oven, and the surface temperature thereof is maintained at 50° C. before lamination. The prepared photosensitive resin film is placed on the low-alkali glass and pressed with a lamination machine (model: CSL-M25E, purchased from C SUN), wherein the temperature and pressure of the lamination machine are 80° C. and 3 kg/cm², respectively, and the laminating speed is 2.0 m/min. After the lamination is completed, an excess film is removed and the resultant photosensitive resin film is allowed to stand for 15 minutes to cool to room temperature.

Subsequently, the photosensitive resin film is exposed by using an exposure machine (model: Contact Aligner, purchased from Deya Optronic). The wavelength of the exposure light source is 365 nm (i line). The exposure is continued until the exposure energy reaches 300 mJ/cm². The aspect ratio of the photoresist pattern to be formed is 2.0, and linear space width: photoresist width of the graphic dimension is 1:1. After the exposure is completed, the exposed photosensitive resin film is baked at 70° C. for 5 minutes.

Then, the exposed photosensitive resin film is developed under the following conditions to obtain the developed photosensitive resin film: propylene glycol methyl ether acetate (PGMEA) is used as a developer, a liquid temperature of 24° C. to 26° C. is set, and an immersion time for performing development is 5 minutes.

A glass cutter is used to cut the developed photosensitive resin film together with the low-alkali glass at an outer edge of a linear space, and the cross-sectional profile of the photoresist pattern is observed with a scanning electron microscope, wherein test pieces are tilted 75° and a magnification of 200 times is used. An upper width is obtained as follows: randomly selecting a photoresist cross-section, measuring the width of the photoresist where the thickness is 1/25, 2/25, 3/25, 4/25 and 5/25 of the total thickness of the photoresist starting from the upper edge of the photoresist (the side away from the low-alkali glass), and averaging the width values measured at these five locations to obtain a value as the upper width. Similarly, a lower width is obtained as follows: randomly selecting a photoresist cross-section, measuring the width of the photoresist where the thickness is 1/25, 2/25, 3/25, 4/25 and 5/25 of the total thickness of the photoresist starting from the lower edge of the photoresist (the side contacting the low-alkali glass), and averaging the width values measured at these five locations to obtain a value as the lower width. If the value of “|(upper width−lower width)|/thickness” is less than 0.04, it is recorded as “rectangular”, which means the cross-sectional shape of the photoresist pattern is good; if the value of “|(upper width−lower width)|/thickness” is 0.04 or higher, it is recorded as “trapezoid”, which means the cross-sectional shape of the photoresist pattern is poor. “|(upper width-lower width)|” in the formula means the absolute value thereof is taken.

### [Footing Length of Photoresist Pattern]

A developed photosensitive resin film is prepared by the same way described in the aforementioned [Cross-sectional shape of photoresist pattern]. Then, a glass cutter is used to cut the developed photosensitive resin film together with the low-alkali glass at an outer edge of a linear space, and a cross-sectional shape of the photoresist pattern is observed with a scanning electron microscope, wherein test pieces are tilted 75° and a magnification of 5000 times is used. A footing length is obtained by randomly selecting a photoresist cross-section and selecting a side in which the bottom protruding more toward the linear space. Specifically, the footing length is obtained by the following calculation: taking the position of a photoresist lateral wall at which the thickness is 1/5 of the total thickness of the photoresist starting from an lower edge of the photoresist as a reference point, extending a baseline perpendicular to an low-alkali glass surface downward from the reference point, and measuring a length from the intersection point of the baseline and the low-alkali glass surface to the intersection point of the photoresist lateral wall and the low-alkali glass surface as a footing length.

### [Light Transmittance]

The prepared composite film comprising the photosensitive resin film is cut into a size of 5 cm×3 cm and the protective films on both surfaces of the photosensitive resin film are removed. A light transmittance of the photosensitive resin film is determined using an ultraviolet-visible spectrophotometer (model: Shimadzu UV-1601, purchased from Shimadzu) in the following manner. The photosensitive resin film is placed on an analysis stage by a fixture, is allowed to be perpendicular to a direction of an incident light source and a light transmittance at wavelength of 550 nm (T550 nm) is measured under the following conditions: an analysis mode of Transmittance is used; a scanning wavelength range of 190 nm to 1100 nm is used; air serves as a blank sample; a scanning speed of 2200 nm/min is used; a switch wavelength at which a light source is switched from a deuterium lamp to a tungsten lamp is 340.8 nm; and a sampling interval of 0.2 nm is used.

### [Silicon Adhesion Testing]

A low-alkali glass with a thickness of 2 mm is preheated at 80° C. for 10 minutes in a batch oven, and the surface temperature thereof is maintained at 50° C. before lamination. The prepared photosensitive resin film is placed on the low-alkali glass and pressed using a lamination machine (model: CSL-M25E, purchased from C SUN) with a temperature of 80° C., a pressure of 3 kg/cm² and a lamination speed of 2.0 m/min. After the lamination is completed, an excess film is removed followed by allowing the obtained photosensitive resin film to stand for 15 minutes to cool to room temperature.

Subsequently, the photosensitive resin film is exposed using an exposure machine (model: Contact Aligner, purchased from Deya Optronic). A wavelength of an exposure light source is 365 nm (i line). The exposure is continued until exposure energy reaches 300 mJ/cm². After the exposure is completed, the exposed photosensitive resin film is baked at 70° C. for 5 minutes.

Then, the exposed photosensitive resin film is developed under the following conditions to obtain the developed pattern-free photosensitive resin film: propylene glycol methyl ether acetate (PGMEA) is used as a developer, a liquid temperature of 24° C. to 26° C. is set, and an immersion time for performing development is 5 minutes.

A bare Si substrate of 3 mm² is placed on a side of the photosensitive resin film that is not in contact with the low-alkali glass, and a pressure of 3 kgf/cm² is applied at 130° C. for 5 minutes to perform bonding. Afterwards, a tensile testing machine is used to determine a force required to tear off the bare Si substrate. In the test, a direction of the force application is parallel to the interface of the bare Si substrate and the photosensitive resin film. The force acts directly on the bare Si substrate, and a specific force application point is located at a middle height of a lateral wall of the bare Si substrate, with the lateral wall being perpendicular to the photosensitive resin film. The unit of adhesion force is kgf/3 mm².

### 4.2. Preparation of Photosensitive Resin Film

The information about the raw materials used in the following examples and comparative examples is shown in Table 1 below.

TABLE 1

| Raw materials | Description |
|---|---|
| BNE200 | Epoxy resin, purchased from Chang Chun Plastics Co., Ltd. |
| BE507 | Epoxy resin, purchased from Chang Chun Plastics Co., Ltd. |
| PNE177 | Epoxy resin, purchased from Chang Chun Plastics Co., Ltd. |
| BNE220 | Epoxy resin, purchased from Chang Chun Plastics Co., Ltd. |
| CNE200ELLA | Epoxy resin, purchased from Chang Chun Plastics Co., Ltd. |
| Celloxide 2021P | Epoxy resin, purchased from DAICEL Co., Ltd. |
| TCM201 | Epoxy resin, purchased from TRONLY Co., Ltd. |
| 3EO TMPTA | Ethylenically unsaturated compound, ethoxylated |
| | trimethylolpropane triacrylate |
| Acetone | Solvent |
| Triphenylsulfonium | Photopolymerization initiator |
| hexafluoroantimonate | |
| Triphenylsulfonium | Photopolymerization initiator |
| tetrakis(pentafluorophenyl)borate | |
| Diphenyliodonium | Photopolymerization initiator |
| tetrakis(pentafluorophenyl)borate | |
| Triarylsulfonium | Photopolymerization initiator |
| tetrakis(pentafluorophenyl)borate | |
| SI-45 | Photopolymerization initiator, purchased from Sanshin |
| | Chemical |
| KBE-403 | Silane coupling agent, CAS number: 2602-34-8 |
| Solvent Blue | Dye, CAS number: 12226-78-7 |
| Oil Blue | Dye, CAS number: 1325-86-6 |
| Solvent Yellow | Dye, CAS number: 176023-34-0 |
| Reactive Yellow | Dye, CAS number: 12226-48-1 |
| Solvent Black | Dye, CAS number: 1333-86-4 |
| Tetrahydrofuran | Solvent |

### Example 1

The following components were mixed and stirred for 5 hours to be evenly mixed, thereby obtaining a resin composition of Example 1:90 parts by weight of BNE200 epoxy resin, 10 parts by weight of BE507 epoxy resin, 25 parts by weight of acetone, 2 parts by weight of triphenylsulfonium hexafluoroantimonate, 5 parts by weight of KBE-403 silane coupling agent, 0.2 parts by weight of Solvent Blue, and 12 parts by weight of tetrahydrofuran.

The resin composition of Example 1 was coated onto a PET film serving as a protective film with a Kodaira wire-wound rod, and the coated resin composition was dried in an oven. Afterwards, a PE film serving as a protective film was stacked on the surface of the dried resin composition, thereby obtaining a photosensitive resin film wrapped by protective films (i.e. a composite film) of Example 1. The conditions of conducting coating and drying are as follows: a coated thickness is 160 μm, a drying temperature of 100° C. is applied, a drying duration of 20 minutes is used, and a thickness after drying is 120 μm.

### Example 2

The following components were mixed and stirred for 5 hours to be evenly mixed, thereby obtaining a resin composition of Example 2:20 parts by weight of BNE200 epoxy resin, 60 parts by weight of BE507 epoxy resin, 20 parts by weight of CNE200ELA epoxy resin, 30 parts by weight of acetone, 1.8 parts by weight of triphenylsulfonium tetrakis(pentafluorophenyl) borate, 5 parts by weight of KBE-403 silane coupling agent, 1.2 parts by weight of Oil Blue, and 12 parts by weight of tetrahydrofuran.

The resin composition of Example 2 was coated onto a PET film serving as a protective film with a Kodaira wire-wound rod, and the coated resin composition was dried in an oven. Afterwards, a PE film serving as a protective film was stacked on the surface of the dried resin composition, thereby obtaining a photosensitive resin film wrapped by protective films (i.e. a composite film) of Example 2. The conditions of conducting coating and drying are as follows: a coated thickness is 25 μm, a drying temperature of 100° C. is applied, a drying duration of 15 minutes is used, and a thickness after drying is 20 μm.

### Example 3

The following components were mixed and stirred for 5 hours to be evenly mixed, thereby obtaining a resin composition of Example 3:30 parts by weight of BNE200 epoxy resin, 20 parts by weight of BE507 epoxy resin, 50 parts by weight of PNE177 epoxy resin, 35 parts by weight of acetone, 4 parts by weight of triphenylsulfonium tetrakis(pentafluorophenyl) borate, 5 parts by weight of KBE-403 silane coupling agent, 0.5 parts by weight of Solvent Blue, and 12 parts by weight of tetrahydrofuran.

The resin composition of Example 3 was coated onto a PET film serving as a protective film with a Kodaira wire-wound rod, and the coated resin composition was dried in an oven. Afterwards, a PE film serving as a protective film was stacked on the surface of the dried resin composition, thereby obtaining a photosensitive resin film wrapped by protective films (i.e. a composite film) of Example 3. The conditions of conducting coating and drying are as follows: a coated thickness is 85 μm, a drying temperature of 90° C. is applied, a drying duration of 19 minutes is used, and a thickness after drying is 60 μm.

### Example 4

The following components were mixed and stirred for 5 hours to be evenly mixed, thereby obtaining a resin composition of Example 4:75 parts by weight of BNE200 epoxy resin, 10 parts by weight of BE507 epoxy resin, 5 parts by weight of BNE220 epoxy resin, 10 parts by weight of 3EO TMPTA (ethylenically unsaturated compound), 25 parts by weight of acetone, 4 parts by weight of triarylsulfonium tetrakis(pentafluorophenyl) borate, 5 parts by weight of KBE-403 silane coupling agent, 0.5 parts by weight of Oil Blue, and 15 parts by weight of tetrahydrofuran.

The resin composition of Example 4 was coated onto a PET film serving as a protective film with a Kodaira wire-wound rod, and the coated resin composition was dried in an oven. Afterwards, a PE film serving as a protective film was stacked on the surface of the dried resin composition, thereby obtaining a photosensitive resin film wrapped by protective films (i.e. a composite film) of Example 4. The conditions of conducting coating and drying are as follows: a coated thickness is 275 μm, a drying temperature of 95° C. is applied, a drying duration of 30 minutes is used, and a thickness after drying is 200 μm.

### Example 5

The following components were mixed and stirred for 5 hours to be evenly mixed, thereby obtaining a resin composition of Example 5:20 parts by weight of BNE200 epoxy resin, 20 parts by weight of BE507 epoxy resin, 20 parts by weight of PNE177 epoxy resin, 20 parts by weight of BNE220 epoxy resin, 10 parts by weight of Celloxide 2021P epoxy resin, 10 parts by weight of TCM201 epoxy resin, 25 parts by weight of acetone, 2 parts by weight of triphenylsulfonium hexafluoroantimonate, 5 parts by weight of KBE-403 silane coupling agent, 0.2 parts by weight of Solvent Blue, and 12 parts by weight of tetrahydrofuran.

The resin composition of Example 5 was coated onto a PET film serving as a protective film with a Kodaira wire-wound rod, and the coated resin composition was dried in an oven. Afterwards, a PE film serving as a protective film was stacked on the surface of the dried resin composition, thereby obtaining a photosensitive resin film wrapped by protective films (i.e. a composite film) of Example 5. The conditions of conducting coating and drying are as follows: a coated thickness is 130 μm, a drying temperature of 100° C. is applied, a drying duration of 20 minutes is used, and a thickness after drying is 100 μm.

### Example 6

The following components were mixed and stirred for 5 hours to be evenly mixed, thereby obtaining a resin composition of Example 6:50 parts by weight of BNE200 epoxy resin, 40 parts by weight of BE507 epoxy resin, 10 parts by weight of BNE220 epoxy resin, 25 parts by weight of acetone, 1.5 parts by weight of triphenylsulfonium hexafluoroantimonate, 0.5 parts by weight of triarylsulfonium tetrakis(pentafluorophenyl) borate, 4 parts by weight of KBE-403 silane coupling agent, 0.3 parts by weight of Solvent Blue, 0.05 parts by weight of Solvent Yellow, and 12 parts by weight of tetrahydrofuran.

The resin composition of Example 6 was coated onto a PET film serving as a protective film with a Kodaira wire-wound rod, and the coated resin composition was dried in an oven. Afterwards, a PE film serving as a protective film was stacked on the surface of the dried resin composition, thereby obtaining a photosensitive resin film wrapped by protective films (i.e. a composite film) of Example 6. The conditions of conducting coating and drying are as follows: a coated thickness is 130 μm, a drying temperature of 90° C. is applied, a drying duration of 25 minutes is used, and a thickness after drying is 100 μm.

### Example 7

The following components were mixed and stirred for 5 hours to be evenly mixed, thereby obtaining a resin composition of Example 7:20 parts by weight of BNE200 epoxy resin, 60 parts by weight of BE507 epoxy resin, 20 parts by weight of PNE177 epoxy resin, 25 parts by weight of acetone, 2 parts by weight of triphenylsulfonium hexafluoroantimonate, 5 parts by weight of KBE-403 silane coupling agent, 0.2 parts by weight of Solvent Blue, and 12 parts by weight of tetrahydrofuran.

The resin composition of Example 7 was coated onto a PET film serving as a protective film with a Kodaira wire-wound rod, and the coated resin composition was dried in an oven. Afterwards, a PE film serving as a protective film was stacked on the surface of the dried resin composition, thereby obtaining a photosensitive resin film wrapped by protective films (i.e. a composite film) of Example 7. The conditions of conducting coating and drying are as follows: a coated thickness is 130 μm, a drying temperature of 100° C. is applied, a drying duration of 20 minutes is used, and a thickness after drying is 100 μm.

### Comparative Example 1

The following components were mixed and stirred for 5 hours to be evenly mixed, thereby obtaining a resin composition of Comparative Example 1:100 parts by weight of Celloxide 2021P epoxy resin, 25 parts by weight of acetone, 0.3 parts by weight of triphenylsulfonium hexafluoroantimonate, 2 parts by weight of SI-45, 5 parts by weight of KBE-403 silane coupling agent, 0.3 parts by weight of Solvent Blue, and 12 parts by weight of tetrahydrofuran.

The resin composition of Comparative Example 1 was coated onto a PET film serving as a protective film with a Kodaira wire-wound rod, and the coated resin composition was dried in an oven. Afterwards, a PE film serving as a protective film was stacked on the surface of the dried resin composition, thereby obtaining a photosensitive resin film wrapped by protective films (i.e. a composite film) of Comparative Example 1. The conditions of conducting coating and drying are as follows: a coated thickness is 130 μm, a drying temperature of 100° C. is applied, a drying duration of 20 minutes is used, and a thickness after drying is 100 μm.

### Comparative Example 2

The following components were mixed and stirred for 5 hours to be evenly mixed, thereby obtaining a resin composition of Comparative Example 2:90 parts by weight of BNE220 epoxy resin, 10 parts by weight of TCM201 epoxy resin, 25 parts by weight of acetone, 1 parts by weight of triphenylsulfonium tetrakis(pentafluorophenyl) borate, 4 parts by weight of triarylsulfonium tetrakis(pentafluorophenyl) borate, 5 parts by weight of KBE-403 silane coupling agent, and 12 parts by weight of tetrahydrofuran.

The resin composition of Comparative Example 2 was coated onto a PET film serving as a protective film with a Kodaira wire-wound rod, and the coated resin composition was dried in an oven. Afterwards, a PE film serving as a protective film was stacked on the surface of the dried resin composition, thereby obtaining a photosensitive resin film wrapped by protective films (i.e. a composite film) of Comparative Example 2. The conditions of conducting coating and drying are as follows: a coated thickness is 85 μm, a drying temperature of 90° C. is applied, a drying duration of 19 minutes is used, and a thickness after drying is 60 μm.

### Comparative Example 3

The following components were mixed and stirred for 5 hours to be evenly mixed, thereby obtaining a resin composition of Comparative Example 3:20 parts by weight of BNE200 epoxy resin, 60 parts by weight of BE507 epoxy resin, 20 parts by weight of CNE200ELA epoxy resin, 30 parts by weight of acetone, 4 parts by weight of triphenylsulfonium tetrakis(pentafluorophenyl) borate, 5 parts by weight of KBE-403 silane coupling agent, 0.06 parts by weight of Solvent Black, and 15 parts by weight of tetrahydrofuran.

The resin composition of Comparative Example 3 was coated onto a PET film serving as a protective film with a Kodaira wire-wound rod, and the coated resin composition was dried in an oven. Afterwards, a PE film serving as a protective film was stacked on the surface of the dried resin composition, thereby obtaining a photosensitive resin film wrapped by protective films (i.e. a composite film) of Comparative Example 3. The conditions of conducting coating and drying are as follows: a coated thickness is 160 μm, a drying temperature of 100° C. is applied, a drying duration of 15 minutes is used, and a thickness after drying is 120 μm.

### Comparative Example 4

The following components were mixed and stirred for 5 hours to be evenly mixed, thereby obtaining a resin composition of Comparative Example 4:30 parts by weight of BNE200 epoxy resin, 20 parts by weight of BE507 epoxy resin, 50 parts by weight of PNE177 epoxy resin, 25 parts by weight of acetone, 2 parts by weight of triphenylsulfonium hexafluoroantimonate, 0.3 parts by weight of diphenyliodonium tetrakis(pentafluorophenyl) borate, 5 parts by weight of KBE-403 silane coupling agent, 0.05 parts by weight of Solvent Blue, and 12 parts by weight of tetrahydrofuran.

The resin composition of Comparative Example 4 was coated onto a PET film serving as a protective film with a Kodaira wire-wound rod, and the coated resin composition was dried in an oven. Afterwards, a PE film serving as a protective film was stacked on the surface of the dried resin composition, thereby obtaining a photosensitive resin film wrapped by protective films (i.e. a composite film) of Comparative Example 4. The conditions of conducting coating and drying are as follows: a coated thickness is 160 μm, a drying temperature of 100° C. is applied, a drying duration of 20 minutes is used, and a thickness after drying is 120 μm.

### Comparative Example 5

The following components were mixed and stirred for 5 hours to be evenly mixed, thereby obtaining a resin composition of Comparative Example 5:20 parts by weight of BNE200 epoxy resin, 60 parts by weight of BE507 epoxy resin, 20 parts by weight of CNE200ELA epoxy resin, 25 parts by weight of acetone, 2 parts by weight of triphenylsulfonium hexafluoroantimonate, 5 parts by weight of KBE-403 silane coupling agent, 0.2 parts by weight of Reactive Yellow, 0.01 parts by weight of Solvent Black, and 15 parts by weight of tetrahydrofuran.

The resin composition of Comparative Example 5 was coated onto a PET film serving as a protective film with a Kodaira wire-wound rod, and the coated resin composition was dried in an oven. Afterwards, a PE film serving as a protective film was stacked on the surface of the dried resin composition, thereby obtaining a photosensitive resin film wrapped by protective films (i.e. a composite film) of Comparative Example 5. The conditions of conducting coating and drying are as follows: a coated thickness is 140 μm, a drying temperature of 95° C. is applied, a drying duration of 20 minutes is used, and a thickness after drying is 100 μm.

### 4.3. Testing of Photosensitive Resin Film

The properties of the photosensitive resin films of Examples 1 to 7 (E1 to E7) and Comparative Examples 1 to 5 (CE1 to CE5) were tested according to the aforementioned testing methods. The results are tabulated in Table 2-1 and Table 2-2.

TABLE 2-1

| | E1 | E2 | E3 | E4 | E5 | E6 | E7 |
|---|---|---|---|---|---|---|---|
| A₃₅₅/T | 0.0070 | 0.0030 | 0.0143 | 0.0300 | 0.0085 | 0.0096 | 0.0082 |
| w1 peak | 610 | 720 | 615 | 710 | 510 | 605 | 616 |
| position (nm) | | | | | | 455 | |
| A_{w1}/T | 0.0031 | 0.0190 | 0.0112 | 0.0095 | 0.0048 | 0.0060 | 0.0012 |
| | | | | | | 0.0045 | |
| A₄₅₀/T | 0.0020 | 0.0010 | 0.0017 | 0.0019 | 0.0024 | 0.0030 | 0.0022 |
| A_{w2}/T | ≤0.003 | ≤0.003 | ≤0.003 | ≤0.003 | ≤0.003 | ≤0.003 | ≤0.003 |
| Film tensile | >2 | >2 | >2 | >2 | >2 | >2 | >2 |
| (g/50 mm) | | | | | | | |
| Shape of | rectangular | rectangular | rectangular | rectangular | rectangular | rectangular | rectangular |
| photoresist | | | | | | | |
| pattern | | | | | | | |
| \|(upper width − | <5 | <5 | <5 | <5 | <5 | 5~10 | <5 |
| lower width)\| | | | | | | | |
| (μm) | | | | | | | |
| Footing length | 2 | 1 | 2 | 2 | 2 | 4 | 2 |
| (μm) | | | | | | | |
| Light | <50% | <50% | <50% | <50% | <50% | <50% | <50% |
| transmittance | | | | | | | |
| T_{550 nm} | | | | | | | |
| Silicon adhesion | 15 | 19 | 18 | 16 | 17 | 14 | 16 |
| (kgf/3 mm²) | | | | | | | |

TABLE 2-2

| | CE1 | CE2 | CE3 | CE4 | CE5 |
|---|---|---|---|---|---|
| A₃₅₅/T | 0.0020 | 0.0350 | 0.0571 | 0.0074 | 0.0063 |
| w1 peak position (nm) | 615 | none | none | 612 | none |
| A_{w1}/T | 0.0057 | — | — | 0.0022 | — |
| A₄₅₀/T | 0.0013 | 0.0016 | 0.0135 | 0.0027 | 0.0038 |
| A_{w2}/T | ≤0.003 | ≤0.003 | >0.003 | ≤0.003 | >0.003 |
| Film tensile (g/50 mm) | <2 | <2 | <2 | >2 | <2 |
| Shape of photoresist | trapezoid | trapezoid | trapezoid | trapezoid | trapezoid |
| pattern | | | | | |
| \|(upper width − lower | >15 | >15 | >15 | >15 | >15 |
| width)\| (μm) | | | | | |
| Footing length (μm) | 30 | 15 | 32 | 22 | 18 |
| Light transmittance | <50% | >50% | <50% | >50% | >50% |
| T_{550 nm} | | | | | |
| Silicon adhesion | 5 | 3 | 4 | 4 | 5 |
| (kgf/3 mm²) | | | | | |

As shown in Table 2-1 and Table 2-2, the photoresist patterns formed after exposure and development of the photosensitive resin films of Examples 1 to 7 of the present application have excellent cross-sectional profile (rectangular cross-section, short footing length) and low light transmittance (550 nanometer wavelength). Examples 1 to 7 further show that if the film tensile of the photosensitive resin film is greater than 2, the silicone adhesion of the photosensitive resin film can be further improved.

In contrast, the photoresist patterns formed after exposure and development of the photosensitive resin films of Comparative Examples 1 to 5 cannot simultaneously have good cross-sectional profile and low light transmittance. Comparative Examples 1 and 3 show that if A₃₅₅/T is lower or higher than the specified range of the present application, the cross-sectional profile of the photoresist pattern will be poor. Comparative Examples 2 and 4 show that if the spectrum does not have at least one point within a first wavelength range where a first derivative equals 0 and a second derivative is less than 0, or if A_{w1}/T within the first wavelength range is less than the specified range of the present application, the photoresist pattern will have poor cross-sectional profile and high light transmittance, which will cause glare problems when applied to the packaging of image sensor chips. Comparative Example 5 shows that if the spectrum does not have at least one point within a first wavelength range where a first derivative equals 0 and a second derivative is less than 0, and the absorbance within the second wavelength range does not satisfy A_{w2}/T≤0.003, the photoresist pattern will have poor cross-sectional profile and high light transmittance, which will cause glare problems when applied to the packaging of image sensor chips.

The above examples are used to illustrate the principle and efficacy of the present application and show the inventive features thereof, but are not used to limit the scope of the present application. People skilled in this field may proceed with a variety of modifications and replacements based on the disclosures and suggestions of the invention as described. Therefore, the scope of protection of the present application is that as defined in the claims as appended.

1. A photosensitive resin film, which has a thickness T in μm,
wherein, when the photosensitive resin film is characterized by ultraviolet-visible spectroscopy, a resulting spectrum has an absorbance A₃₅₅ at 355 nm, and 0.003<A₃₅₅/T≤0.03;
the spectrum has at least one point within a first wavelength range where a first derivative equals 0 and a second derivative is less than 0, and the point each independently has an A_{w1}/T value, wherein w1 represents a corresponding wavelength of the point, A_{w1} represents a corresponding absorbance, and 0.003≤A_{w1}/T; and
the first wavelength range is from greater than 450 nm to 780 nm, and the thickness T ranges from 20 μm to 200 μm.

2. The photosensitive resin film of claim 1, wherein 0.003≤A_{w1}/T≤0.08.

3. The photosensitive resin film of claim 1, wherein the ultraviolet-visible spectroscopy is measured by using an ultraviolet-visible spectrophotometer under the following conditions: the photosensitive resin film is placed perpendicularly to a direction of incident light;
a diffraction grating is configured as an optical splitter; testing temperature is 25° C.; testing pressure is 1 atm; an analysis mode is absorbance; a range of scanned wavelength is from 190 nm to 1100 nm; a blank sample is air; scan velocity is 2200 nm/min; a switch wavelength at which a light source is switched from a deuterium lamp to a tungsten lamp is 340.8 nm; a sampling interval is 0.2 nm; and a slit width is 2.0 nm.

4. The photosensitive resin film of claim 1, wherein the spectrum has an absorbance A₄₅₀ at 450 nm, and 0<A₄₅₀/T≤0.003.

5. The photosensitive resin film of claim 1, wherein the first wavelength range is from greater than 480 nm to 730 nm.

6. The photosensitive resin film of claim 5, wherein an absorbance of the spectrum at each wavelength within a second wavelength range is independently denoted as A_{w2}, with w2 representing wavelength of corresponding absorbance, and wherein 0≤A_{w2}/T≤0.003, and the second wavelength range is from 440 nm to 470 nm.

7. The photosensitive resin film of claim 1, which is a negative dry film.

8. The photosensitive resin film of claim 4, which is a negative dry film.

9. The photosensitive resin film of claim 6, which is a negative dry film.

10. The photosensitive resin film of claim 1, which comprises an epoxy resin.

11. The photosensitive resin film of claim 4, which comprises an epoxy resin.

12. The photosensitive resin film of claim 6, which comprises an epoxy resin.

13.-15. (canceled)

16. A composite film, comprising:
the photosensitive resin film of claim 1; and
a protective film on at least one surface of the photosensitive resin film.

17. A package structure, comprising:
a substrate;
a semiconductor element electrically connected to the substrate; and
a package for encapsulating the semiconductor element,
wherein a material of the package comprises a cured product of the photosensitive resin film of claim 1.

18. The package structure of claim 17, wherein:
the semiconductor element is an image sensor chip, and the image sensor chip has a photosensitive area; and
the material of the package comprises a first portion formed from a cured product of the photosensitive resin film of claim 1, and a second portion formed from a transparent material, with the first portion laterally surrounding the image sensor chip and the second portion being disposed above the photosensitive area.
